(19) United States
(12) Patent Application Publication
(10) Pub. No.: US 2024/0250066 A1
(43) Pub. Date: Jul. 25, 2024

(54) SEMICONDUCTOR PACKAGE

(71) Applicant: Samsung Electronics Co., Ltd., Suwon-si (KR)

(72) Inventors: Joonghyun BAEK, Suwon-si (KR); Hyungu KANG, Suwon-si (KR); Cheol-Woo LEE, Suwon-si (KR); Sunghwan YOON, Suwon-si (KR); Eunjeong IM, Suwon-si (KR)

(73) Assignee: Samsung Electronics Co., Ltd., Suwon-si (KR)

(21) Appl. No.: 18/535,339

(22) Filed: Dec. 11, 2023

(30) Foreign Application Priority Data
Jan. 25, 2023 (KR) 10-2023-0009759

(51) Int. Cl. H01L 25/065; H01L 23/00; H01L 23/31; H01L 23/538; H01L 25/10

(52) U.S. Cl. CPC H01L 25/0652; H01L 23/3128; H01L 23/5381; H01L 24/32; H01L 24/48; H01L 24/73; H01L 25/105; H01L 2224/32145; H01L 2224/32225; H01L 2224/48145; H01L 2224/48227; H01L 2224/73215; H01L 2225/06506; H01L 2225/0651; H01L 2225/06562

(57) ABSTRACT

A semiconductor package including first and second chip stacks each including semiconductor chips having an offset stack structure, the second chip stack horizontally spaced apart from the first chip stack, a first buffer chip on the substrate and at a side of the first chip stack, a second buffer chip on the substrate and at a side of the second chip stack, a connection substrate on the first and second chip stacks, a first mold layer covering the substrate, the first chip stack, and the second stack and exposing a top surface of the connection substrate, third and fourth chip stacks each including semiconductor chips having an offset stack structure on the first mold layer and, the fourth chip stack horizontally spaced apart from the third chip stack, and a second mold layer covering the first mold layer, the third chip stack, and the fourth chip stack may be provided.

### CROSS-REFERENCE TO RELATED APPLICATIONS

This U.S. non-provisional patent application claims priority under 35 U.S.C. § 119 to Korean Patent Application No. 10-2023-0009759, filed on Jan. 25, 2023, in the Korean Intellectual Property Office, the entire contents of which are hereby incorporated by reference.

### BACKGROUND

The present disclosure relates to semiconductor packages, and in particular, to semiconductor packages including a plurality of stacked semiconductor chips.

As the demand for high-capacity memory devices grows in response to the needs of information technology (IT) devices, the use of high-capacity NAND FLASH products, which are provided in the form of a semiconductor package, is being continuously increasing. To meet this demand, methods of stacking a plurality of semiconductor chips during the assembly process to achieve the required high capacity, instead of increasing memory capacity through the wafer-level fabrication process, has been used in a semiconductor packaging technology. The stacking of the semiconductor chips can be accomplished by stacking the chips in an upward or downward direction or by stacking the chips in a specific direction but in a zigzag pattern.

### SUMMARY

Some example embodiments of the inventive concepts provide large-capacity semiconductor packages.

Some example embodiments of the inventive concepts provide high-performance semiconductor packages.

According to an example embodiment of the inventive concepts, a semiconductor package includes a first chip stack including first semiconductor chips, the first semiconductor chips on a substrate and having an offset stack structure, a second chip stack on the substrate and horizontally spaced apart from the first chip stack, the second chip stack including second semiconductor chips, the second semiconductor chips having an offset stack structure, a first buffer chip on the substrate and at a side of the first chip stack, a second buffer chip on the substrate and at a side of the second chip stack, a connection substrate on the first and second chip stacks, a first mold layer covering the substrate, the first chip stack, and the second chip stack, the first mold layer exposing a top surface of the connection substrate, a third chip stack including third semiconductor chips, the third semiconductor chips on the first mold layer and having an offset stack structure, a fourth chip stack on the first mold layer and horizontally spaced apart from the third chip stack, the fourth chip stack including fourth semiconductor chips, the fourth semiconductor chips having an offset stack structure, and a second mold layer covering the first mold layer, the third chip stack, and the fourth chip stack.

According to an example embodiment of the inventive concepts, a semiconductor package includes a first chip stack including first semiconductor chips, the first semiconductor chips on a substrate and having an offset stack structure, a second chip stack on the substrate and horizontally spaced apart from the first chip stack, the second chip stack including second semiconductor chips, the second semiconductor chips having an offset stack structure, a first buffer chip on the substrate and at a side of the first chip stack, a second buffer chip on the substrate and at a side of the second chip stack such that the first chip stack and the second chip stack are between the first buffer chip and the second buffer chip, a connection substrate on the first and second chip stacks, a first mold layer covering the substrate, the first chip stack, and the second chip stack, the first molding layer exposing a top surface of the connection substrate, a third chip stack including third semiconductor chips, the third semiconductor chips on the first mold layer and having an offset stack structure, a fourth chip stack on the first mold layer and horizontally spaced apart from the third chip stack, the fourth chip stack including fourth semiconductor chips, the fourth semiconductor chips having an offset stack structure, and a second mold layer covering the first mold layer, the third chip stack, and the fourth chip stack, wherein each of the first to fourth semiconductor chips comprises a chip pad provided on a top surface thereof, the semiconductor package further comprises first to fourth wires, each of the first to fourth wires connected to the chip pad of a corresponding one of the first to fourth semiconductor chips, the first wire connects the chip pad of a lowermost one of the first semiconductor chips to the substrate, the second wire connects the chip pad of a lowermost one of the second semiconductor chips to the substrate, the third wire connects the chip pad of a lowermost one of the third semiconductor chips to the substrate, the fourth wire connects the chip pad of a lowermost one of the fourth semiconductor chips to the substrate, and end portions of the third and fourth wires are exposed to an outside at a bottom surface of the second mold layer, and wherein the semiconductor package further comprises a fifth wire in the first mold layer and connecting the third wire to the substrate, a sixth wire in the first mold layer and connecting the fourth wire to the substrate, a seventh wire in the first mold layer and connected to the first buffer chip, the seventh wire having an end portion exposed to an outside at a top surface of the first mold layer, an eighth wire in the first mold layer and connected to the second buffer chip, the eighth wire having an end portion exposed to an outside at the top surface of the first mold layer, a ninth wire in the second mold layer and connecting the chip pad of one of the third semiconductor chips to the seventh wire, and a tenth wire in the second mold layer and connecting the chip pad of one of the fourth semiconductor chips to the eighth wire.

According to an example embodiment of the inventive concepts, a semiconductor package includes a first chip stack including first semiconductor chips, the first semiconductor chips on a substrate and having an offset stack structure, a second chip stack including second semiconductor chips, the second semiconductor chips on the first chip stack and having an offset stack structure, a first buffer chip on the substrate and at a side of the first chip stack, a second buffer chip on the substrate and at an opposite side of the first chip stack, a connection substrate on the second chip stack, a first mold layer covering the substrate, the first chip stack, and the second chip stack, the first mold layer exposing a top surface of the connection substrate, a third chip stack including third semiconductor chips, the third semiconductor chips on the first mold layer and having an offset stack structure, a fourth chip stack including fourth semiconductor chips, the fourth semiconductor chips on the third chip stack and having an offset stack structure, and a second mold layer covering the first mold layer, the third chip stack, and the fourth chip stack.

### BRIEF DESCRIPTION OF THE DRAWINGS

FIG. 1 is a plan view illustrating a semiconductor package according to an example embodiment of the inventive concepts.

FIG. 2 is a sectional view taken along a line I-I′ of FIG. 1.

FIG. 3 is an enlarged sectional view of a portion ‘A’ of FIG. 2.

FIG. 4 is a plan view concretely illustrating a bonding surface of wires.

FIGS. 5A to 5D are sectional views sequentially illustrating a process of fabricating the semiconductor package of FIG. 2.

FIG. 6A is a sectional view illustrating a semiconductor package according to an example embodiment of the inventive concepts.

FIG. 6B is a sectional view illustrating a semiconductor package according to an example embodiment of the inventive concepts.

FIG. 7 is a plan view illustrating a semiconductor package according to an example embodiment of the inventive concepts.

FIG. 8 is a sectional view taken along a line II-II′ of FIG. 7.

### DETAILED DESCRIPTION

Example embodiments of the inventive concepts will now be described more fully with reference to the accompanying drawings, in which some example embodiments are shown.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

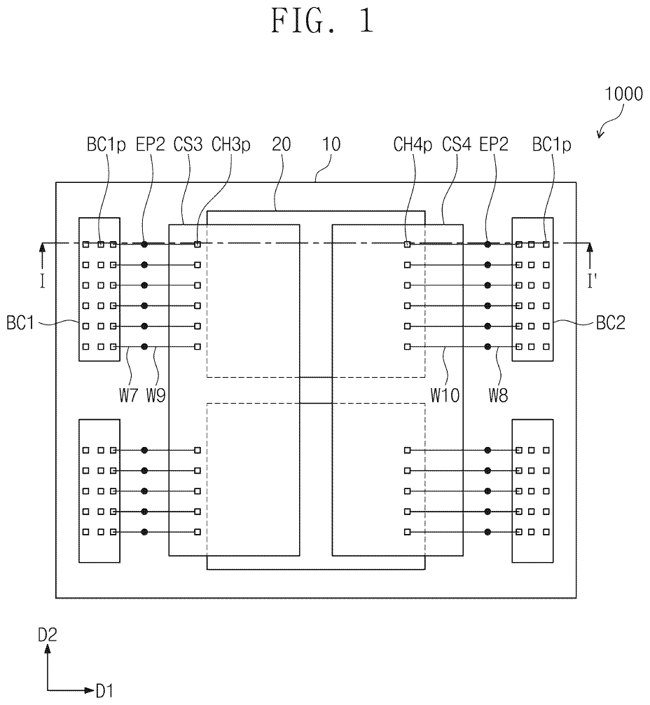

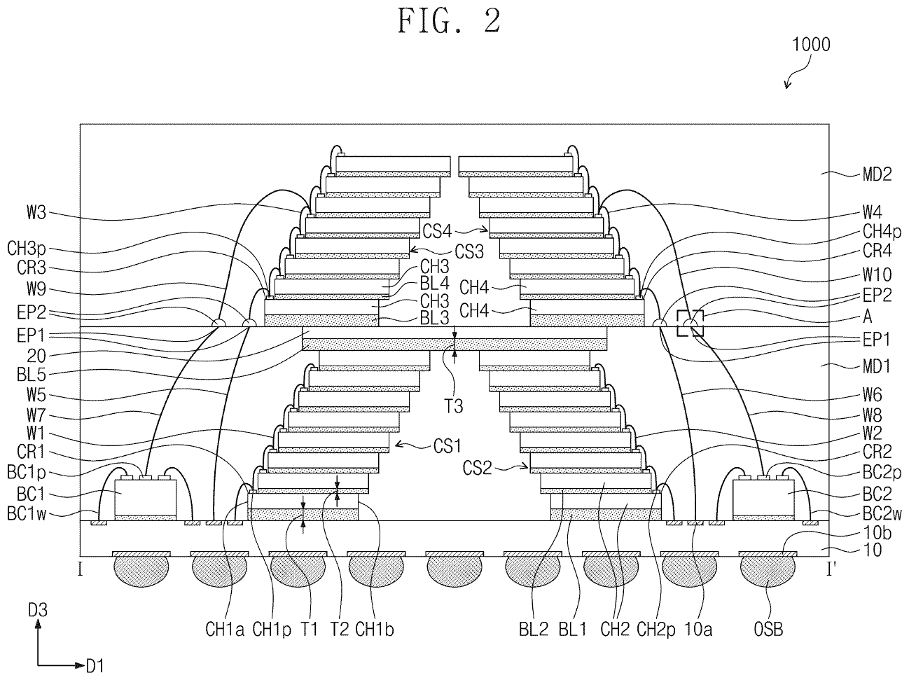

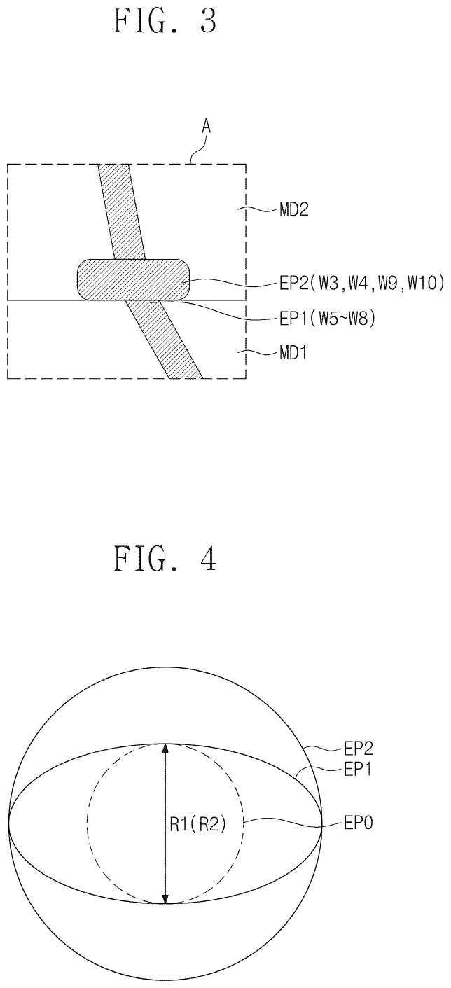

FIG. 1 is a plan view illustrating a semiconductor package according to an example embodiment of the inventive concepts, FIG. 2 is a sectional view taken along a line I-I′ of FIG. 1, FIG. 3 is an enlarged sectional view of a portion ‘A’ of FIG. 2, and FIG. 4 is a plan view concretely illustrating a bonding surface of wires.

Referring to FIGS. 1 and 2, a semiconductor package 1000 may include a substrate 10, a first chip stack CS1, a second chip stack CS2, a third chip stack CS3, a fourth chip stack CS4, a first buffer chip BC1, a second buffer chip BC2, a connection substrate 20, a first mold layer MD1, and a second mold layer MD2.

The substrate 10 may be a printed circuit board (PCB), which has a substrate upper pad 10a provided on a top surface thereof. The substrate upper pad 10a may be formed of or include a conductive material (e.g., copper). The substrate 10 may have a structure, in which insulating patterns and interconnection patterns are alternately stacked on top of one another. Outer connection terminals OSB may be provided on a bottom surface of the substrate 10. The outer connection terminals OSB may include solder balls, solder bumps, or solder pads. Depending on the kind of the outer connection terminals OSB, the substrate 10 may have a ball grid array (BGA) structure, a fine ball-grid array (FBGA) structure, or a land grid array (LGA) structure.

The first chip stack CS1 may be provided on the substrate 10. The first chip stack CS1 may include first semiconductor chips CH1, which are stacked on the substrate 10 in a third direction D3. In the present specification, a first direction D1 and a second direction D2 may be parallel to a top surface of the substrate 10 but not to each other, and the third direction D3 may be perpendicular to the top surface of the substrate 10.

The first semiconductor chips CH1 may be memory chips. For example, the first semiconductor chips CH1 may include a dynamic random access memory (DRAM) chip. The number of the first semiconductor chips CH1 may be n. In an example embodiment, the number n may be eight. However, the number of the first semiconductor chips CH1 is not limited to eight.

The first semiconductor chips CH1 may have a first side surface CH1a and a second side surface CH1b, which are opposite to each other in the first direction D1. For example, the first side surface CH1a may be a side surface of the first semiconductor chip CH1, which is placed in an opposite direction of the first direction D1, and the second side surface CH1b may be a side surface of the first semiconductor chip CH1, which is placed in the first direction D1.

The first semiconductor chips CH1 may be disposed in an offset stack structure. For example, the first semiconductor chips CH1 may be stacked to be inclined in the first direction D1, thereby forming an upwardly-inclined staircase structure or a cascade structure. For example, each of the first semiconductor chips CH1 may protrude from an underlying first semiconductor chip in the first direction D1.

Because the first semiconductor chips CH1 are stacked in a stepwise shape (e.g., a staircase shape), the first semiconductor chips CH1 may have top surfaces that are partially exposed to the outside. In each of the first semiconductor chips CH1, the exposed portion of the top surface of the first semiconductor chip may be referred to as a first connection region CR1. In accordance with an offset stacking direction of the first semiconductor chips CH1, the first connection regions CR1 may be located adjacent to the first side surfaces CHla of the first semiconductor chips CH1. Here, the offset stacking direction may be defined as a direction, in which each semiconductor chip is shifted from another semiconductor chip thereunder. For example, in the example embodiment of FIG. 1, the offset stacking direction of the first semiconductor chips CH1 may be the first direction D1.

The top surface of the first semiconductor chip CH1 may be an active surface. First chip pads CH1p may be respectively provided on the first connection regions CR1 of the top surfaces of the first semiconductor chips CH1. The first chip pads CH1p may be connected to integrated circuits of the first semiconductor chips CH1.

The first semiconductor chips CH1 may be connected to the substrate 10 in a wire bonding manner. The first semiconductor chips CH1 may be connected to the substrate 10 through first wires W1. Hereinafter, for convenience in description, a lower one of the first semiconductor chips CH1, which are adjacent to each other, will be referred to as a lowest first semiconductor chip. The lowest one of the first semiconductor chips CH1 may be connected to the substrate 10 through the first wire W1.

A first adhesive layer BL1 may be provided under a bottom surface of the lowermost one of the first semiconductor chips CH1. The first adhesive layer BL1 may be interposed between the lowest first semiconductor chip CH1 and the substrate 10 and may have a first thickness T1.

Second adhesive layers BL2 may be provided under bottom surfaces of the first semiconductor chips CH1, respectively. Each of the first semiconductor chips CH1 may be attached to an underlying one of the first semiconductor chips CH1 using the second adhesive layer BL2. The second adhesive layer BL2 may be interposed between the first semiconductor chips CH1 and may have a second thickness T2.

The first thickness T1 of the first adhesive layer BL1 may be larger than the second thickness T2 of the second adhesive layer BL2, and in this case, the first chip stack CS1 may be more stably placed on the substrate 10. The first thickness T1 of the first adhesive layer BL1 may range from 20 μm to 40 μm, and the second thickness T2 of the second adhesive layer BL2 may range from 5 μm to 20 μm. Each of the first and second adhesive layers BL1 and BL2 may include a die attach film (DAF).

Referring to FIGS. 1 and 2, the second chip stack CS2 may be disposed on the substrate 10. The second chip stack CS2 may be horizontally spaced apart from the first chip stack CS1. The second chip stack CS2 may be spaced apart from the first chip stack in the first direction D1. In other words, the second chip stack CS2 may be configured to face the second side surfaces CH1b of the first semiconductor chips CH1. A thickness of the second chip stack CS2 may be equal to a thickness of the first chip stack CS1.

The second chip stack CS2 may include second semiconductor chips CH2, which are stacked on the substrate 10 in the third direction D3. The second semiconductor chips CH2 may be memory chips. For example, the second semiconductor chips CH2 may include a NAND flash memory chip. The number of the second semiconductor chips CH2 may be n. In an example embodiment, the number n may be eight. However, the number of the second semiconductor chips CH2 is not limited to eight.

The second semiconductor chips CH2 may be disposed to have an offset stack structure. For example, the second semiconductor chips CH2 may be stacked to be sequentially shifted in the opposite direction of the first direction D1, thereby forming an upwardly-inclined staircase structure or a cascade structure. For example, each of the second semiconductor chips CH2 may protrude from an underlying second semiconductor chip CH2 in the opposite direction of the first direction D1.

Because the second semiconductor chips CH2 are stacked in a stepwise shape (e.g., a staircase shape), the second semiconductor chips CH2 may have top surfaces that are partially exposed to the outside. In each of the second semiconductor chips CH2, the exposed portion of the top surface of the second semiconductor chip CH2 may be referred to as a second connection region CR2. In accordance with an offset stacking direction of the second semiconductor chips CH2, the second connection region CR2 may be located adjacent to a side surface of the second semiconductor chip CH2 placed in the first direction D1. The top surface of the second semiconductor chip CH2 may be an active surface. For example, second chip pads CH2p may be provided on the second connection regions CR2 of the top surfaces of the second semiconductor chips CH2, respectively. The second chip pads CH2p may be connected to integrated circuits of the second semiconductor chips CH2.

The second semiconductor chip CH2 may be connected to the substrate 10 in a wire bonding manner. The second semiconductor chips CH2 may be connected to each other through second wires W2. Hereinafter, for convenience in description, a lower one of the second semiconductor chips CH2, which are adjacent to each other, will be referred to as the lowest second semiconductor chip. The lowest second semiconductor chip CH2 may be connected to the substrate 10 through the second wire W2.

An adhesive layer may be provided under a bottom surface of each of the second semiconductor chips CH2 and may be the same as the adhesive layer provided under the bottom surface of each of the first semiconductor chips CH1 in terms of their shape or structure.

The connection substrate 20 may be provided on the first and second chip stacks CS1 and CS2. A width of the connection substrate 20 may be larger than a sum of widths of the uppermost ones of the first and second semiconductor chips CH1 and CH2, which will be referred to as the uppermost first semiconductor chip and the uppermost second semiconductor chip, respectively. The connection substrate 20 may overlap the uppermost first semiconductor chip CH1 or the uppermost second semiconductor chip CH2, when viewed in a plan view.

The connection substrate 20 may include a bare silicon wafer, an organic substrate, or an organic film. A thickness of the connection substrate 20 may range from 5 μm to 30 μm.

The connection substrate 20 may be attached to a top surface of the uppermost first semiconductor chip CH1 and a top surface of the uppermost second semiconductor chip CH2 using a fifth adhesive layer BL5. The fifth adhesive layer BL5 may be interposed between the connection substrate 20 and the first chip stack CS1. The fifth adhesive layer BL5 may be interposed between the connection substrate 20 and the second chip stack CS2. The fifth adhesive layer BL5 may cover the entire top surface of the uppermost first semiconductor chip CH1 and the entire top surface of the uppermost second semiconductor chip CH2. Here, the first chip pad CH1p of the uppermost first semiconductor chip CH1 and the second chip pad CH2p of the uppermost second semiconductor chip CH2 may be covered with the fifth adhesive layer BL5.

In an example embodiment, a portion of the first wire W1 of the uppermost first semiconductor chip CH1 and a portion of the second wire W2 of the uppermost second semiconductor chip may be respectively inserted into the fifth adhesive layer BL5. The fifth adhesive layers BL5 may include a die attach film (DAF). The fifth adhesive layer BL5 may have a third thickness T3. Because the third and fourth chip stacks CS3 and CS4 are stacked on the connection substrate 20, in order to ensure a structural stability of the semiconductor package, the fifth adhesive layer BL5 under the connection substrate 20 and the first adhesive layer BL1 under the lowest first semiconductor chip CH1 may be provided in such a way that the third thickness T3 is equal to the thickness of the first adhesive layer BL1 or the thickness of the third adhesive layer BL3 (e.g., the first thickness T1). In other words, the third thickness T3 of the fifth adhesive layer BL5 may be larger than the second thickness T2 of the second adhesive layer BL2, which is interposed between the first semiconductor chips CH1.

Meanwhile, the first mold layer MD1 may be provided on the substrate 10. The first mold layer MD1 may cover the first chip stack CS1, the second chip stack CS2, and the connection substrate 20. The first mold layer MD1 may expose a top surface of the connection substrate 20 and cover the first chip stack CS1, the second chip stack CS2, and the connection substrate 20. The first mold layer MD1 may be formed of or include an insulating polymer material (e.g., an epoxy molding compound (EMC)).

The third and fourth chip stacks CS3 and CS4 may be disposed on the connection substrate 20 and the first mold layer MD1.

The third chip stack CS3 may be provided on the connection substrate 20 and the first mold layer MD1. The third chip stack CS3 may include third semiconductor chips CH3, which are stacked on the connection substrate 20 and the first mold layer MD1 and are stacked in the third direction D3. The third chip stack CS3 may overlap the first chip stack CS1, when viewed in a plan view.

The third semiconductor chips CH3 may be memory chips. For example, the third semiconductor chips CH3 may include a dynamic random access memory (DRAM). The number of the third semiconductor chips CH3 may be m. In an example embodiment, the number m may be eight. However, the number of the third semiconductor chips CH3 is not limited to eight. In the case where the third chip stack CS3 is staked to vertically overlap the first chip stack CS1, the first and third chip stacks CS1 and CS3 may include semiconductor chips that are stacked to form (m+n) layers. In an example embodiment, the number (m+n) may be 16. However, the stacked semiconductor chips, which are included in the first and third chip stacks CS1 and CS3, may not be limited to the 16 layers.

Each of the third semiconductor chips CH3 may have a first side surface and a second side surface, which are opposite to each other in the first direction D1. For example, the first side surface may be a side surface of the third semiconductor chip CH3, which is placed in the opposite direction of the first direction D1, and the second side surface CH3b be a side surface of the third semiconductor chip CH3, which is placed in the first direction D1.

The third semiconductor chips CH3 may be disposed to have an offset stack structure. For example, the third semiconductor chips CH3 may be stacked to be inclined in the first direction D1, thereby forming an upwardly-inclined staircase structure or a cascade structure. For example, each of the third semiconductor chips CH3 may protrude from an underlying third semiconductor chip in the first direction D1.

Because the third semiconductor chips CH3 are stacked in a stepwise shape (e.g., a staircase shape), the third semiconductor chips CH3 may have top surfaces that are partially exposed to the outside. In each of the third semiconductor chips CH3, the exposed portion of the top surface of the third semiconductor chip CH3 may be referred to as a third connection region CR3. In accordance with an offset stacking direction of the third semiconductor chips CH3, the third connection regions CR3 may be located adjacent to the first side surfaces of the third semiconductor chips CH3.

The top surface of the third semiconductor chip CH3 may be an active surface. For example, third chip pads CH3p may be provided on the third connection region CR3 of the top surface of the third semiconductor chips CH3. The third chip pads CH3p may be connected to integrated circuits of the third semiconductor chips CH3.

The third semiconductor chips CH3 may be connected to the substrate 10 in a wire bonding manner. The third semiconductor chips CH3 may be connected to each other through third wires W3. Hereinafter, for convenience in description, a lower one of the third semiconductor chips CH3, which are adjacent to each other, will be referred to as a lowest third semiconductor chip CH3. The lowest third semiconductor chip may be connected to the substrate 10 through the third wire W3. An end portion EP2 of the third wire W3 may be exposed to the outside of the second mold layer MD2 at or near a bottom surface of the second mold layer MD2. The end portion EP2 of the third wire W3 may be connected to a fifth wire W5 disposed in the first mold layer MD1. The fifth wire W5 may connect the third wire W3 to the substrate 10.

A third adhesive layer BL3 may be provided under a bottom surface of the lowermost one of the third semiconductor chips CH3. The third adhesive layer BL3 may be interposed between the lowest third semiconductor chip CH3 and the first mold layer MD1 and may have the first thickness T1.

A fourth adhesive layer BL4 may be provided under a bottom surface of each of the third semiconductor chips CH3. Each of the third semiconductor chips CH3 may be attached to an underlying one of the third semiconductor chips CH3 using the fourth adhesive layer BL4. The fourth adhesive layer BL4 may be interposed between the third semiconductor chips CH3 and may have the second thickness T2.

The thickness of the third adhesive layer BL3 may be larger than the thickness of the fourth adhesive layer BL4, and in this case, the third chip stack CS3 may be more stably placed on the first mold layer MD1. The thickness of the third adhesive layer BL3 may be the first thickness T1, and the thickness of the fourth adhesive layer BL4 may be the second thickness T2. The first thickness T1 of the third adhesive layer BL3 may range from 20 μm to 40 μm, and the second thickness T2 of the fourth adhesive layer BL4 may range from 5 μm to 20 μm. The third and fourth adhesive layers BL3 and BL4 may include a die attach film (DAF).

Meanwhile, the fourth chip stack CS4 may be disposed on the first mold layer MD1 and the connection substrate 20 to be parallel to the third chip stack CS3. The fourth chip stack CS4 may be horizontally spaced apart from the third chip stack CS3. The fourth chip stack CS4 may be spaced apart from the third chip stack CS3 in the first direction D1. In other words, the fourth chip stack CS4 may face the second side surfaces CH3b of the third semiconductor chips CH3. A thickness of the fourth chip stack CS4 may be equal to a thickness of the third chip stack CS3. The fourth chip stack CS4 may overlap the second chip stack CS2, when viewed in a plan view.

The fourth chip stack CS4 may include fourth semiconductor chips CH4, which are stacked on the substrate 10 in the third direction D3. The fourth semiconductor chips CH4 may be memory chips. For example, the fourth semiconductor chips CH4 may include a NAND flash memory chip. The number of the fourth semiconductor chips CH4 may be m. In an example embodiment, the number m may be eight. However, the number of the fourth semiconductor chips CH4DML is not limited to eight. In the case where the fourth chip stack CS4 is stacked to vertically overlap the second chip stack CS2, the second and fourth chip stacks CS2 and CS4 may include semiconductor chips that are stacked form (m+n) layers. In an example embodiment, the number (m+n) may be 16. However, the stacked semiconductor chips, which are included in the second and fourth chip stacks CS2 and CS4, may not be limited to the 16 layers.

The fourth semiconductor chips CH4 may be disposed to have an offset stack structure. For example, the fourth semiconductor chips CH4 may be stacked to be sequentially shifted in the opposite direction of the first direction D1, thereby forming an upwardly-inclined staircase structure or a cascade structure. For example, each of the fourth semiconductor chips CH4 may protrude from an underlying fourth semiconductor chip in the opposite direction of the first direction D1.

Because the fourth semiconductor chips CH4 are stacked in a stepwise shape (e.g., a staircase shape), the fourth semiconductor chips CH4 may have top surfaces that are partially exposed to the outside. In each of the fourth semiconductor chips CH3, the exposed portion of the top surface of the fourth semiconductor chip CH4 may be referred to as a fourth connection region CR4. In accordance with an offset stacking direction of the fourth semiconductor chips CH4, the fourth connection region CR4 may be located adjacent to a side surface of the fourth semiconductor chip CH4 placed in the first direction D1. The top surface of the fourth semiconductor chip CH4 may be an active surface. For example, fourth chip pads CH4p may be provided on the fourth connection regions CR4 of the top surfaces of the fourth semiconductor chips CH4, respectively. The fourth chip pads CH4p may be connected to integrated circuits of the fourth semiconductor chips CH4.

The fourth semiconductor chip CH4 may be connected to the substrate 10 in a wire bonding manner. The fourth semiconductor chips CH4 may be connected to each other through fourth wires W4. Hereinafter, for convenience in description, a lower one of the fourth semiconductor chips CH4, which are adjacent to each other, will be referred to as a lowest fourth semiconductor chip. The lowest fourth semiconductor chip may be connected to the substrate 10 through the fourth wire W4. An end portion EP1 of a sixth wire W6 in the first mold layer MD1 may be exposed to the outside of the first mold layer MD1 at or near a top surface of the first mold layer MD1. An end portion EP2 of the fourth wire W4 may be exposed to the outside of the second mold layer MD2 at or near the bottom surface of the second mold layer MD2. The end portion EP2 of the fourth wire W4 may be connected to the end portion EP1 of the sixth wire W6. The sixth wire W6 may connect the fourth wire W4 to the substrate 10.

An adhesive layer may be provided under a bottom surface of each of the fourth semiconductor chips CH4 and may be the same as the adhesive layer provided under the bottom surface of each of the third semiconductor chips CH3 in terms of their shape or structure.

Meanwhile, the second mold layer MD2 may be provided on the first mold layer MD1. The second mold layer MD2 may cover the third and fourth chip stacks CS3 and CS4. The second mold layer MD2 may be formed of or include an insulating polymer material (e.g., an epoxy molding compound (EMC)), which is different from that of the first mold layer MD1.

Because, as described above, the third and fourth chip stacks CS3 and CS4 are disposed on the top surface of the first mold layer MD1, the first mold layer MD1 may be used to support the third and fourth chip stacks CS3 and CS4, and thus, the first mold layer MD1 may have a large mechanical strength. For example, the mechanical strength of the first mold layer MD1 may be larger than a mechanical strength of the second mold layer MD2.

Meanwhile, the first and second buffer chips BC1 and BC2 may be disposed on the substrate 10. The first buffer chip BC1 may be disposed on the substrate 10 and at a side of the first chip stack CS1, and the second buffer chip BC2 may be disposed on the substrate 10 and at a side of the second chip stack CS2 that is opposite to the side of the first chip stack in the first direction D1 where the first buffer chip BC1 is disposed. In other words, the second buffer chip BC2 may be disposed on the substrate 10 and at a side of the second chip stack CS2 such that the first chip stack CS1 and the second chip stack CS2 are disposed between the first buffer chip BC1 and the second buffer chip BC2. The first buffer chip BC1 may be electrically connected to the third chip stack CS3, and the second buffer chip BC2 may be electrically connected to the fourth chip stack CS4.

Each of the first and second buffer chips BC1 and BC2 may be a buffer chip, which includes a random access memory device. The buffer chip may include a volatile memory device (e.g., a dynamic random access memory (DRAM) device or a static random access memory (SRAM) device). In some example embodiments, the first and second buffer chips BC1 and BC2 may be logic chips, such as a controller.

The first buffer chip BC1 may include a plurality of first buffer chip pads BC1p provided on a top surface thereof, and the second buffer chip BC2 may include a plurality of second buffer chip pads BC2p provided on a top surface thereof. The first and second buffer chip pads BC1p and BC2p may be formed of or include at least one of conductive materials. For example, the first and second buffer chip pads BC1p and BC2p may be formed of or include at least one of gold (Au), silver (Ag), copper (Cu), nickel (Ni), or aluminum (Al).

At least one of the first buffer chip pads BC1p may be electrically connected to the substrate 10 through a first chip wire BC1w, and at least one of the second buffer chip pads BC2p may be electrically connected to the substrate 10 through a second chip wire BC2w. At least one of the first buffer chip pads BC1p and at least one of the second buffer chip pads BC2p may be connected to the substrate upper pad 10a of the substrate 10.

Referring to FIGS. 2, 3, and 4, a seventh wire W7 may be disposed in the first mold layer MD1 and may be connected to the first buffer chip BC1. The seventh wire W7 may be connected to one of the first buffer chip pads BC1p of the first buffer chip BC1. The seventh wire W7 may have an end portion EP1, which is exposed to the outside of the first mold layer MD1 at or near the top surface of the first mold layer MD1. An end portion of the seventh wire W7 may be connected to one of the first buffer chip pads BC1p, and an opposite end portion EP1 of the seventh wire W7 may be connected to a ninth wire W9, which will be described below. An end portion EP0 of the seventh wire W7 may have a circular section with a first diameter R1. Here, the first diameter R1 may range from 10 μm to 30 μm. The opposite end portion EP1 of the seventh wire W7 may have an elliptical section at or near the top surface of the first mold layer MD1.

An eighth wire W8 may be disposed in the first mold layer MD1 and may be connected to the second buffer chip BC2. The eighth wire W8 may be connected to one of the second buffer chip pads BC2p of the second buffer chip BC2. The eighth wire W8 may have an end portion EP1, which is exposed to the outside of the first mold layer MD1 at or near the top surface of the first mold layer MD1. An end portion of the eighth wire W8 may be connected to one of the second buffer chip pads BC2p, and an opposite end portion EP1 of the eighth wire W8 may be connected to a tenth wire W10, which will be described below. An end portion EP0 of the eighth wire W8 may have a circular section with a second diameter R2. Here, the second diameter R2 may range from 10 μm to 30 μm. The opposite end portion EP1 of the eighth wire W8 may have an elliptical section with long and short axes, at or near the top surface of the first mold layer MD1. Here, a length of the opposite end portion EP1 of the eighth wire W8 in the direction of the short axis may be substantially equal to the first diameter R1.

A ninth wire W9 may be disposed in the second mold layer MD2. The ninth wire W9 may be in contact with the seventh wire W7. The ninth wire W9 may be connected to one of the third chip pads CH3p of the third semiconductor chips CH3. The ninth wire W9 may connect one of the third chip pads CH3p of the third semiconductor chips CH3 to the seventh wire W7. The ninth wire W9 may include an end portion EP0, which is connected to one of the third chip pads CH3p, and an opposite end portion EP2, which is connected to the end portion EP1 of the seventh wire W7. The end portion EP0 of the ninth wire W9 may have a circular section with the first diameter R1. The opposite end portion EP2 of the ninth wire W9 may have a circular section whose diameter is larger than the first diameter R1.

A tenth wire W10 may be disposed in the second mold layer MD2. The tenth wire W10 may be in contact with the eighth wire W8. The tenth wire W10 may be connected to one of the fourth chip pads CH4p of the fourth semiconductor chips CH4. The tenth wire W10 may connect one of the fourth chip pads CH4p of the fourth semiconductor chips CH4 to the eighth wire W8. The tenth wire W10 may include an end portion EP0, which is connected to one of the fourth chip pads CH4p, and an opposite end portion EP2, which is connected to the end portion EP1 of the eighth wire W8. The end portion EP0 of the tenth wire W10 may have a circular section with the first diameter R1. The opposite end portion EP2 of the tenth wire W10 may have a circular section whose diameter is larger than the first diameter R1.

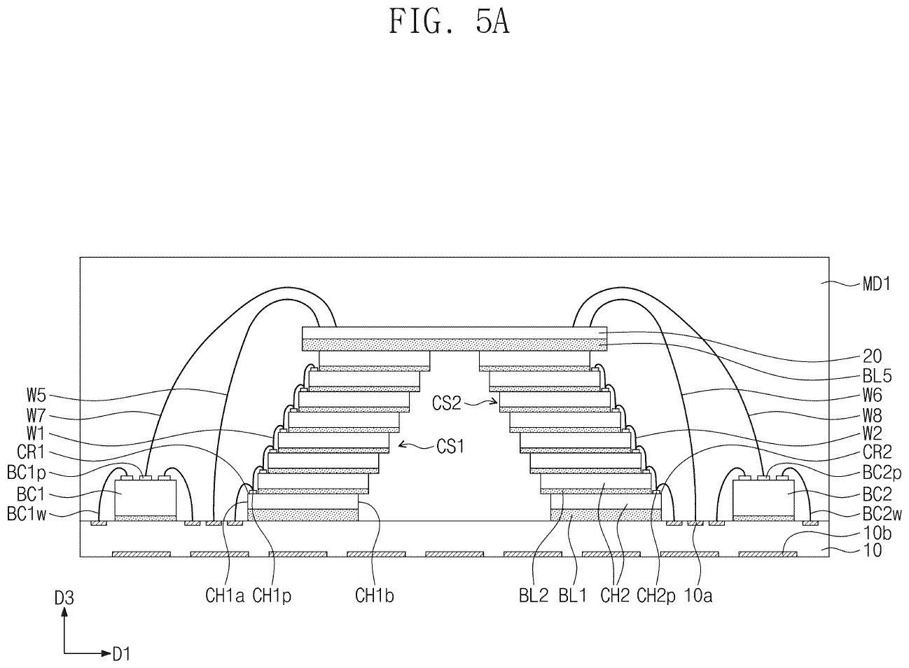

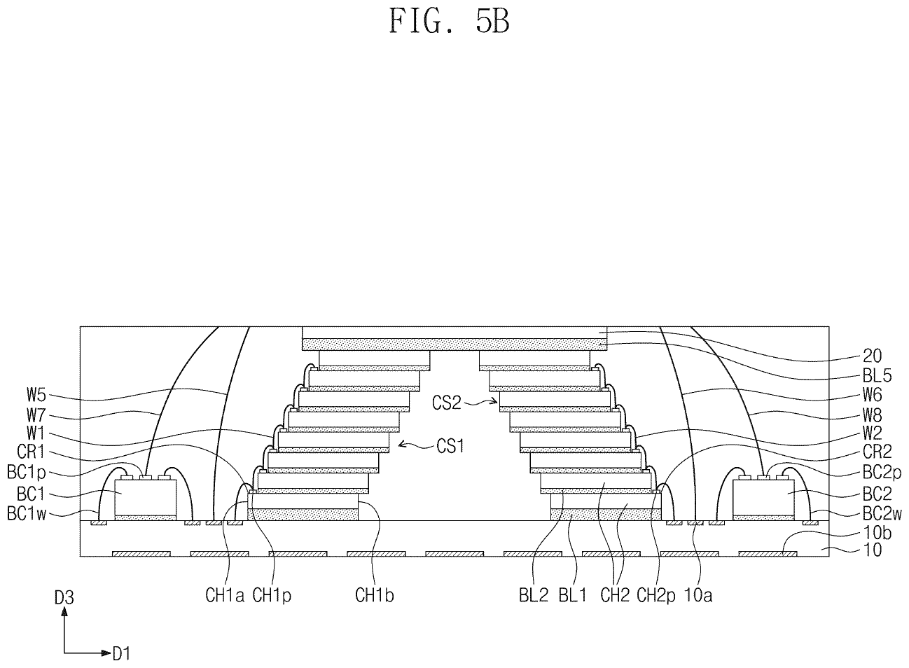

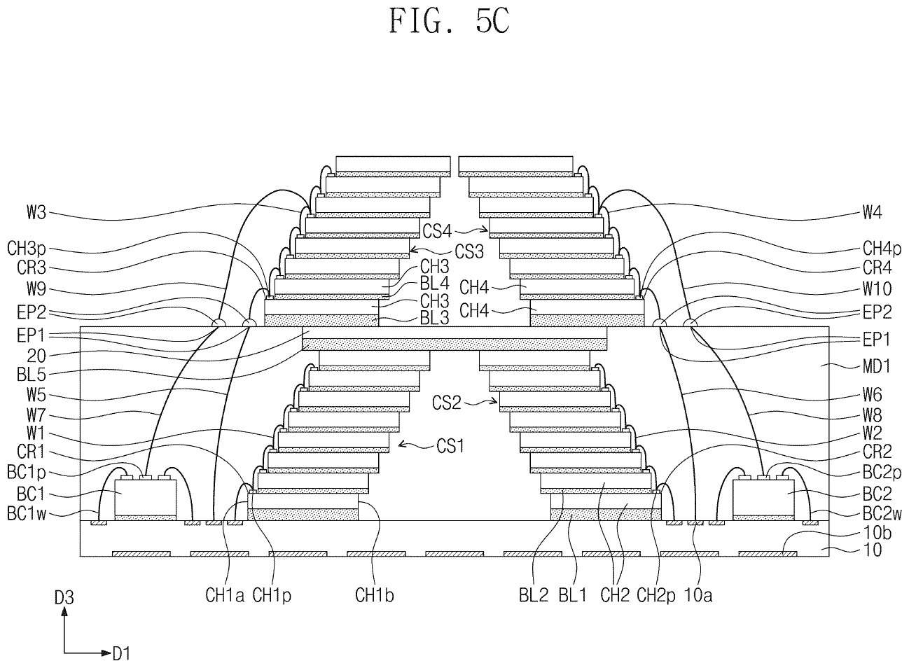

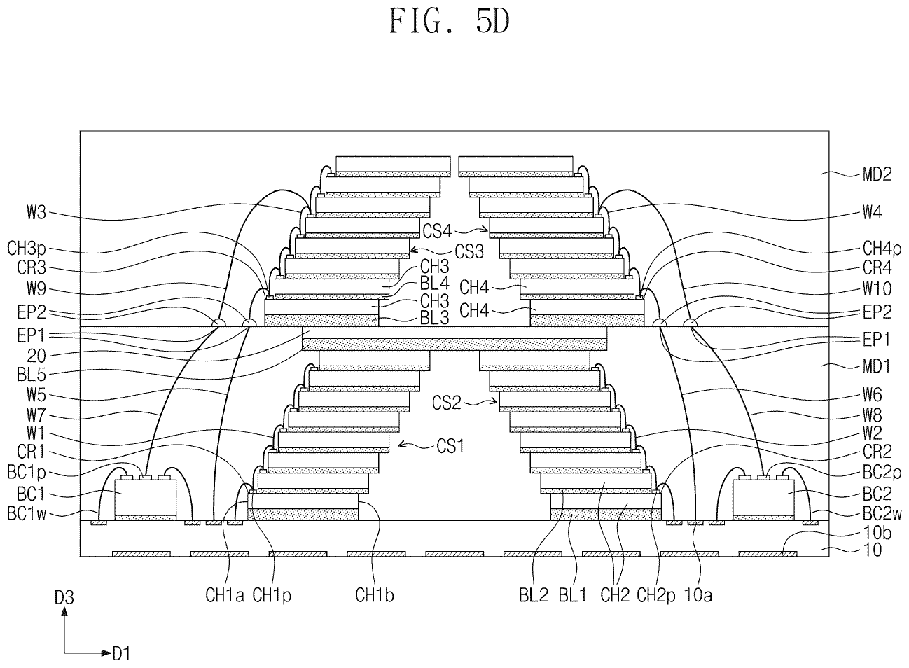

FIGS. 5A to 5D are sectional views sequentially illustrating a process of fabricating the semiconductor package of FIG. 2.

Referring to FIG. 5A, the first and second chip stacks CS1 and CS2 and the first and second buffer chips BC1 and BC2 may be disposed on the substrate 10. The connection substrate 20 may be disposed on the first and second chip stacks CS1 and CS2. Next, the first mold layer MD1 may be formed on the substrate to cover the first chip stack CS1, the second chip stack CS2, and the connection substrate 20.

Referring to FIG. 5B, a grinding process may be performed on the first mold layer MD1 to expose the top surface of the connection substrate 20. Thus, the fifth to eighth wires W5 to W8, which are placed in the first mold layer MD1 and are connected to the connection substrate 20, may be partially removed. A portion of each of the fifth to eighth wires W5 to W8, which are located at a level higher than the top surface of the connection substrate 20, may be removed by the grinding process. Thus, each of the fifth to eighth wires W5 to W8 may include an end portion that is exposed to the outside at or near the top surface of the first mold layer MD1.

Referring to FIG. 5C, the third and fourth chip stacks CS3 and CS4 may be disposed on the first mold layer MD1. The ninth wire W9, which is connected to one of chip pads of the third semiconductor chips CH3 of the third chip stack CS3, may be disposed to be in contact with the seventh wire W7. The tenth wire W10, which is connected to one of chip pads of the fourth semiconductor chips CH4 of the fourth chip stack CS4, may be disposed to be in contact with the eighth wire W8.

Referring to FIG. 5D, the second mold layer MD2 may be formed on the first mold layer MD1 to cover the third and fourth chip stacks CS3 and CS4. The second mold layer MD2 may be formed to fully cover the third and fourth chip stacks CS3 and CS4.

Referring back to FIG. 2, the outer connection terminals OSB may be bonded to the bottom surface of the substrate 10. Substrate lower pads 10b may be disposed under the bottom surface of the substrate. The substrate lower pad 10b may be formed of or include a conductive material (e.g., copper). The outer connection terminals OSB may be bonded to bottom surfaces of the substrate lower pads 10b. The outer connection terminals OSB may be in contact with the bottom surfaces of the substrate lower pads 10b. The outer connection terminals OSB may be formed of or include at least one of conductive materials (e.g., nickel (Ni), tin (Sn), or silver (Ag)).

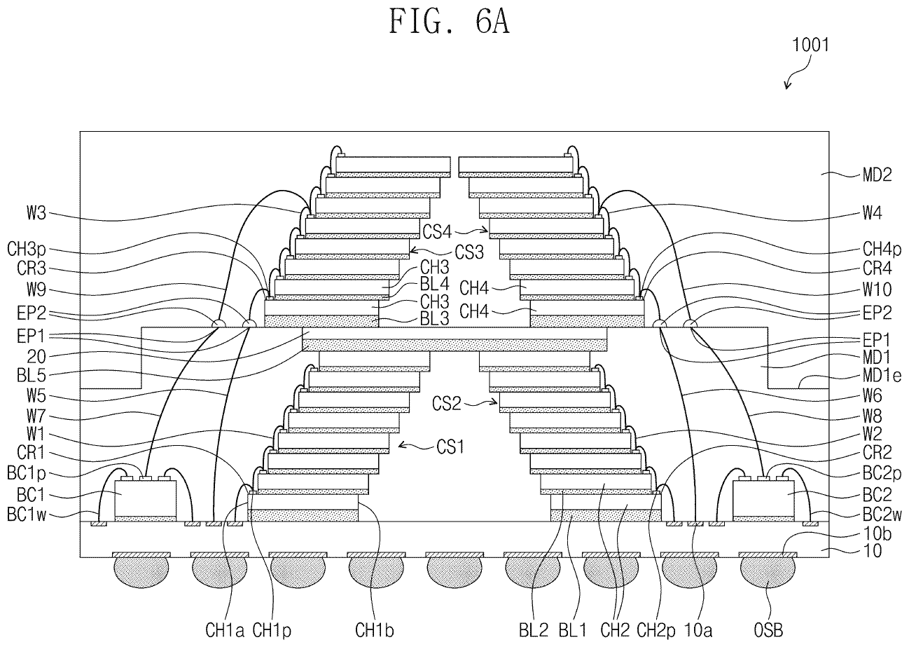

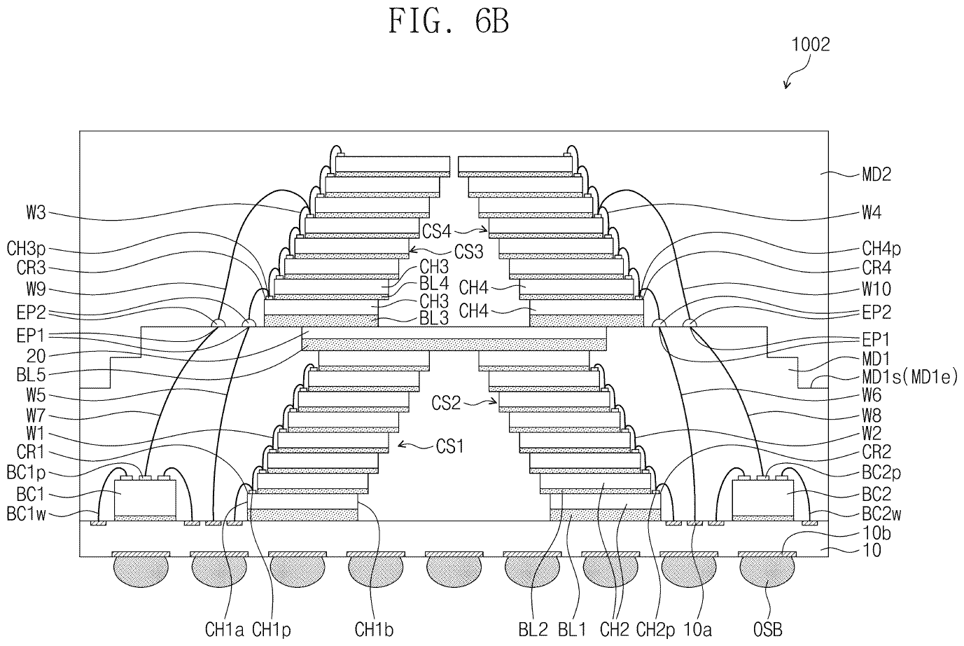

FIG. 6A is a sectional view illustrating a semiconductor package according to an example embodiment of the inventive concepts.

In a semiconductor package 1001, an edge of the top surface of the first mold layer MD1 may be provided in a stepwise shape. Except for this difference, the semiconductor package 1001 may be configured to have substantially the same features as the semiconductor package 1000 of FIGS. 1 to 5D, and thus, for concise description, an afore-described element may be identified by the same reference number without repeating an overlapping description thereof.

Referring to FIG. 6A, an edge MD1e of the top surface of the first mold layer MD1 may be formed in a stepwise shape. As described above, the second mold layer MD2 may be disposed on the first mold layer MD1, and the bottom surface of the second mold layer MD2 may be fittingly engaged with the top surface of the first mold layer MD1. Due to the stepwise shape of the edge of the top surface of the first mold layer MD1, a contact area between the first and second mold layers MD1 and MD2, which are fittingly engaged with each other, may be increased. Thus, an adhesion strength between the first and second mold layers MD1 and MD2 may be increased.

FIG. 6B is a sectional view illustrating a semiconductor package according to an example embodiment of the inventive concepts.

In a semiconductor package 1002, the edge MD1e of the top surface of the first mold layer MD1 may have a stepwise recessed shape. Except for this difference, the semiconductor package 1002 may be configured to have substantially the same features as the semiconductor package 1000 of FIGS. 1 to 5D, and thus, for concise description, an afore-described element may be identified by the same reference number without repeating an overlapping description thereof.

Referring to FIG. 6B, the edge MD1e of the top surface of the first mold layer MD1 may be formed in a stepwise shape, and in an example embodiment, it may include a plurality of stepwise portions MDIs. The edge MD1e of the top surface of the first mold layer MD1 may have a stepwise structure composed of the stepwise portions MDIs. The bottom surface of the second mold layer MD2 may be fittingly engaged with the top surface of the first mold layer MD1. Because the stepwise portions MDIs are formed in the edge of the top surface of the first mold layer MD1, a contact area between the first and second mold layers MD1 and MD2, which are fittingly engaged with each other, may be further increased. Thus, an adhesion strength between the first and second mold layers MD1 and MD2 may be increased.

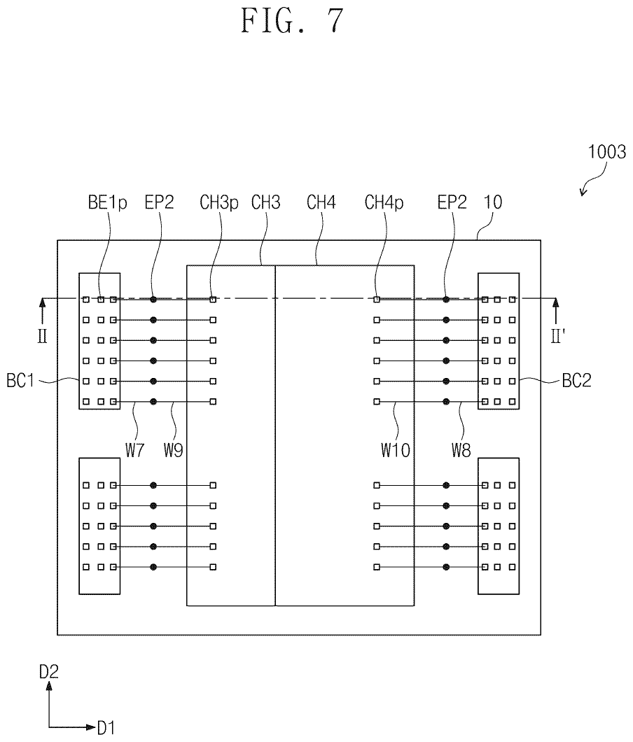

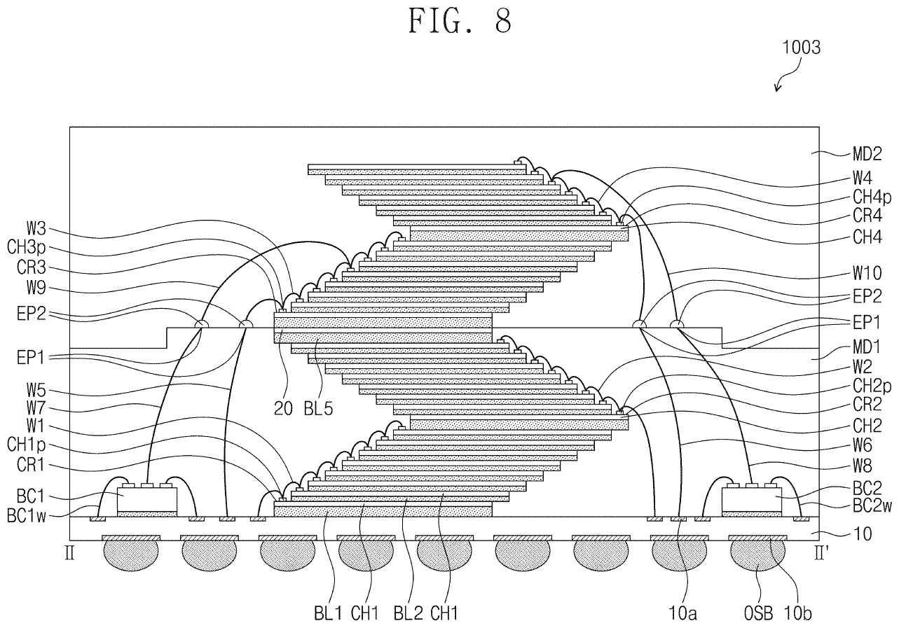

FIG. 7 is a plan view illustrating a semiconductor package according to an example embodiment of the inventive concepts, and FIG. 8 is a sectional view taken along a line II-II′ of FIG. 7.

In a semiconductor package 1003, the second chip stack CS2 may be disposed on the first chip stack CS1, and the fourth chip stack CS4 may be disposed on the third chip stack CS3. Except for this difference, the semiconductor package 1003 may be configured to have substantially the same features as the semiconductor package 1000 of FIGS. 1 to 5D, and thus, for concise description, an afore-described element may be identified by the same reference number without repeating an overlapping description thereof.

Referring to FIGS. 7 and 8, the first semiconductor chips CH1 of the first chip stack CS1 may be disposed to have an offset stack structure. For example, the first semiconductor chips CH1 may be stacked to be sequentially shifted in the first direction D1, thereby forming an upwardly-inclined staircase structure or a cascade structure.

The second chip stack CS2 may be disposed on the first chip stack CS1. The second semiconductor chips CH2 of the second chip stack CS2 may be disposed to have an offset stack structure. For example, the second semiconductor chips CH2 may be stacked to be sequentially shifted in the opposite direction of the first direction D1, thereby forming an upwardly-inclined staircase structure or a cascade structure.

The first buffer chip BC1 may be disposed at a side of the first chip stack CS1 and the second buffer chip BC2 may be disposed at an opposite side of the first or second chip stack CS1 or CS2.

The connection substrate 20 may be disposed on the second chip stack CS2. The connection substrate 20 may be disposed on the uppermost second semiconductor chip of the second chip stack CS2. The first mold layer MD1 may cover the top surface of the substrate 10, the first chip stack CS1, the second chip stack CS2, and the connection substrate 20 but expose the top surface of the connection substrate 20.

The third chip stack CS3 may be disposed on the connection substrate 20. The third semiconductor chips CH3 of the third chip stack CS3 may have an offset stack structure. For example, the third semiconductor chips CH3 may be stacked to be sequentially shifted in the first direction D1, thereby forming an upwardly-inclined staircase structure or a cascade structure.

The fourth chip stack CS4 may be disposed on the third chip stack CS3. The fourth semiconductor chips CH4 of the fourth chip stack CS4 may have an offset stack structure. For example, the fourth semiconductor chips CH4 may be stacked to be sequentially shifted in the opposite direction of the first direction D1, thereby forming an upwardly-inclined staircase structure or a cascade structure.

The second mold layer MD2 may be disposed on the first mold layer MD1. The second mold layer MD2 on the first mold layer MD1 may cover the top surface of the first mold layer MD1, the third chip stack CS3, and the fourth chip stack CS4.

Except for the above features, the semiconductor package may be configured to have substantially the same features as those of the semiconductor package described with reference to FIGS. 1 to 4D.

According to some example embodiments of the inventive concepts, a semiconductor package may include a plurality of semiconductor chips (e.g., memory chips), which are stacked using a connection substrate to form multiple (e.g., 16) layers, and thus, it may be possible to realize a semiconductor package, which has a large storage capacity and improved memory performance, within a given mounting area.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor package, comprising:
a first chip stack including first semiconductor chips, the first semiconductor chips on a substrate and having an offset stack structure;
a second chip stack on the substrate and horizontally spaced apart from the first chip stack, the second chip stack including second semiconductor chips, the second semiconductor chips having an offset stack structure;
a first buffer chip on the substrate and at a side of the first chip stack;
a second buffer chip on the substrate and at a side of the second chip stack;
a connection substrate on the first and second chip stacks;
a first mold layer covering the substrate, the first chip stack, and the second chip stack, the first mold layer exposing a top surface of the connection substrate;
a third chip stack including third semiconductor chips, the third semiconductor chips on the first mold layer and having an offset stack structure;
a fourth chip stack on the first mold layer and horizontally spaced apart from the third chip stack, the fourth chip stack including fourth semiconductor chips, the fourth semiconductor chips having an offset stack structure; and
a second mold layer covering the first mold layer, the third chip stack, and the fourth chip stack.

2. The semiconductor package of claim 1, wherein a number of each of the first to fourth semiconductor chips is eight.

3. The semiconductor package of claim 1, wherein
each of the first to fourth semiconductor chips comprises a chip pad on a top surface thereof,
the semiconductor package further comprises first to fourth wires, each of the first to fourth wires connected to the chip pad of a corresponding one of the first to fourth semiconductor chips,
the first wire connects the chip pad of a lowermost one of the first semiconductor chips to the substrate,
the second wire connects the chip pad of a lowermost one of the second semiconductor chips to the substrate,
the third wire connects the chip pad of a lowermost one of the third semiconductor chips to the substrate, and
the fourth wire connects the chip pad of a lowermost one of the fourth semiconductor chips to the substrate.

4. The semiconductor package of claim 3, wherein
end portions of the third and fourth wires are exposed to an outside at a bottom surface of the second mold layer,
the semiconductor package further comprises,
a fifth wire disposed in the first mold layer to connect the third wire to the substrate, and
a sixth wire disposed in the first mold layer to connect the fourth wire to the substrate.

5. The semiconductor package of claim 4, further comprising:
a seventh wire in the first mold layer and connected to the first buffer chip, the seventh wire having an end portion exposed to an outside at a top surface of the first mold layer; and
an eighth wire in the first mold layer and connected to the second chip, the eighth wire having an end portion exposed to an outside at the top surface of the first mold layer.

6. The semiconductor package of claim 5, further comprising:
a ninth wire in the second mold layer, the ninth wire connecting the chip pad on one of the third semiconductor chips to the seventh wire; and
a tenth wire in the second mold layer, the tenth wire connecting the chip pad on one of the fourth semiconductor chips to the eighth wire,
wherein the seventh wire has a first circular section on the top surface of the first mold layer, the first circular section having a first diameter,
the eighth wire has a second circular section on the top surface of the first mold layer, the second circular section having a second diameter,
the ninth wire is in contact with the seventh wire and has a first end portion, the first end portion having an elliptical shape with long and short axes, and
the tenth wire is in contact with the eighth wire and has a second end portion, the second end portion having an elliptical shape with long and short axes.

7. The semiconductor package of claim 1, wherein
the connection substrate comprises a bare silicon wafer, an organic substrate, or an organic film, and
a thickness of the connection substrate ranges from 5 μm to 30 μm.

8. The semiconductor package of claim 1, further comprising:
a first adhesive layer between a lowermost one of the first semiconductor chips and the substrate, the first adhesive layer having a first thickness; and
a second adhesive layer between the first semiconductor chips, the second adhesive layer having a second thickness,
wherein the first thickness is larger than the second thickness.

9. The semiconductor package of claim 8, further comprising:
a third adhesive layer between a lowermost one of the third semiconductor chips and the first mold layer, the third adhesive layer having a third thickness; and
a fourth adhesive layer between the third semiconductor chips, the fourth adhesive layer having a fourth thickness.

10. The semiconductor package of claim 9, further comprising:
a fifth adhesive layer between the connection substrate and the first chip stack, the fifth adhesive layer having a fifth thickness,
wherein the fifth thickness is equal to at least one of the first thickness or the third thickness.

11. The semiconductor package of claim 10, wherein
the first, third, and fifth thicknesses range from 20 μm to 40 μm, and
the second thickness and fourth thickness range from 5 μm to 20 μm.

12. The semiconductor package of claim 1, wherein the first and second mold layers include materials different from each other.

13. The semiconductor package of claim 1, wherein a mechanical strength of the first mold layer is larger than a mechanical strength of the second mold layer.

14. The semiconductor package of claim 1, wherein
an edge of a top surface of the first mold layer has a stepwise structure, and
a bottom surface of the second mold layer is fittingly engaged with the top surface of the first mold layer.

15. A semiconductor package, comprising:
a first chip stack including first semiconductor chips, the first semiconductor chips on a substrate and having an offset stack structure;
a second chip stack on the substrate and horizontally spaced apart from the first chip stack, the second chip stack including second semiconductor chips, the second semiconductor chips having an offset stack structure;
a first buffer chip on the substrate and at a side of the first chip stack;
a second buffer chip on the substrate and at a side of the second chip stack such that the first chip stack and the second chip stack are between the first buffer chip and the second buffer chip;
a connection substrate on the first and second chip stacks;
a first mold layer covering the substrate, the first chip stack, and the second chip stack, the first molding layer exposing a top surface of the connection substrate;
a third chip stack including third semiconductor chips, the third semiconductor chips on the first mold layer and having an offset stack structure;
a fourth chip stack on the first mold layer and horizontally spaced apart from the third chip stack, the fourth chip stack including fourth semiconductor chips, the fourth semiconductor chips having an offset stack structure; and
a second mold layer covering the first mold layer, the third chip stack, and the fourth chip stack,
wherein each of the first to fourth semiconductor chips comprises a chip pad provided on a top surface thereof,
the semiconductor package further comprises first to fourth wires, each of the first to fourth wires connected to the chip pad of a corresponding one of the first to fourth semiconductor chips,
the first wire connects the chip pad of a lowermost one of the first semiconductor chips to the substrate,
the second wire connects the chip pad of a lowermost one of the second semiconductor chips to the substrate,
the third wire connects the chip pad of a lowermost one of the third semiconductor chips to the substrate,
the fourth wire connects the chip pad of a lowermost one of the fourth semiconductor chips to the substrate, and
end portions of the third and fourth wires are exposed to an outside at a bottom surface of the second mold layer, and
wherein the semiconductor package further comprises
a fifth wire in the first mold layer and connecting the third wire to the substrate,
a sixth wire in the first mold layer and connecting the fourth wire to the substrate,
a seventh wire in the first mold layer and connected to the first buffer chip, the seventh wire having an end portion exposed to an outside at a top surface of the first mold layer,
an eighth wire in the first mold layer and connected to the second buffer chip, the eighth wire having an end portion exposed to an outside at the top surface of the first mold layer,
a ninth wire in the second mold layer and connecting the chip pad of one of the third semiconductor chips to the seventh wire, and
a tenth wire in the second mold layer and connecting the chip pad of one of the fourth semiconductor chips to the eighth wire.

16. A semiconductor package, comprising:
a first chip stack including first semiconductor chips, the first semiconductor chips on a substrate and having an offset stack structure;
a second chip stack including second semiconductor chips, the second semiconductor chips on the first chip stack and having an offset stack structure;
a first buffer chip on the substrate and at a side of the first chip stack;
a second buffer chip on the substrate and at an opposite side of the first chip stack;
a connection substrate on the second chip stack;
a first mold layer covering the substrate, the first chip stack, and the second chip stack, the first mold layer exposing a top surface of the connection substrate;
a third chip stack including third semiconductor chips, the third semiconductor chips on the first mold layer and having an offset stack structure;
a fourth chip stack including fourth semiconductor chips, the fourth semiconductor chips on the third chip stack and having an offset stack structure; and
a second mold layer covering the first mold layer, the third chip stack, and the fourth chip stack.

17. The semiconductor package of claim 16, wherein
each of the first to fourth semiconductor chips comprises a chip pad on a top surface thereof,
the semiconductor package further comprises first to fourth wires, each of the first to fourth wires connected to the chip pad of a corresponding one of the first to fourth semiconductor chips,
the first wire connects the chip pad of a lowermost one of the first semiconductor chips to the substrate,
the second wire connects the chip pad of a lowermost one of the second semiconductor chips to the substrate,
the third wire connects the chip pad of a lowermost one of the third semiconductor chips to the substrate, and
the fourth wire connects the chip pad of a lowermost one of the fourth semiconductor chips to the substrate.

18. The semiconductor package of claim 17, wherein
end portions of the third and fourth wires are exposed to an outside at a bottom surface of the second mold layer,
the semiconductor package further comprises,
a fifth wire in the first mold layer and connecting the third wire to the substrate, and
a sixth wire in the first mold layer and connecting the fourth wire to the substrate.

19. The semiconductor package of claim 18, further comprising:
a seventh wire in the first mold layer and connected to the first buffer chip, the seventh wire having an end portion exposed to an outside at a top surface of the first mold layer; and
an eighth wire in the first mold layer and connected to the second chip, the eighth wire having an end portion exposed to an outside at the top surface of the first mold layer.

20. The semiconductor package of claim 19, further comprising:
a ninth wire in the second mold layer, the ninth wire connecting the chip pad one of the third semiconductor chips to the seventh wire; and
a tenth wire in the second mold layer, the tenth wire connecting the chip pad of one of the fourth semiconductor chips to the eighth wire.
